(19) United States
(12) Patent Application Publication
(10) Pub. No.: US 2009/0098676 A1
(43) Pub. Date: Apr. 16, 2009

(54) METHOD OF MANUFACTURING LIGHT EMITTING DIODE

(75) Inventors: Reiko SOEJIMA, Yamanashi (JP); Keiichi YUI, Yamanashi (JP); Kazuhiko HORINO, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 12/249,462

(22) Filed: Oct. 10, 2008

(30) Foreign Application Priority Data
Oct. 12, 2007 (JP) 2007-266166

(51) Int. Cl. H01L 21/00; H01L 21/28

(52) U.S. Cl. 438/46; 438/604; 257/E33.028

(57) ABSTRACT

A method of manufacturing a light emitting diode includes forming an active layer of a nitride semiconductor on a first conductive type of a nitride semiconductor layer, thermally treating the active layer at a first temperature, and forming a second conductive type of a nitride semiconductor layer on the active layer at a second temperature lower than the first temperature.

### BACKGROUND OF THE INVENTION

1. Field of the Invention

The present invention relates to a method of manufacturing a light emitting diode, and more particularly to a method of manufacturing a light emitting diode including nitride semiconductor layers.

2. Description of the Related Art

Some light emitting elements such as a white light emitting diode (LED) employ an LED including nitride semiconductor layers.

Such an LED including nitride semiconductor layers has a low electrostatic discharge (ESD) breakdown tolerance voltage. In order to improve an ESD tolerance voltage of an LED including nitride semiconductor layers, Japanese Patent Application Publication No. 8-330630 discloses a technique of forming an additional p-type clad layer between an active layer and a p-type clad layer in an LED.

### SUMMARY OF THE INVENTION

The present invention has been made in view of the above. It is, therefore, an object of the present invention to improve an ESD tolerance voltage of an LED in a simple way.

According to an aspect of the present invention, there is provided a method of manufacturing a light emitting diode to improve an ESD tolerance voltage of an LED in a simple way. In this method, an active layer of a nitride semiconductor is formed on a first conductive type of a nitride semiconductor layer. The active layer is thermally treated at a first temperature. Then a second conductive type of a nitride semiconductor layer is formed on the active layer at a second temperature lower than the first temperature. With this method, an ESD tolerance voltage of the LED can be improved.

In the above method, the second conductive type of the nitride semiconductor layer may be formed of one of GaN, AlGaN, and AlInGaN. Furthermore, the active layer may be formed of one of InGaN/GaN, InGaN/InGaN, and AlInGaN/AlInGaN. Moreover, the active layer and/or the second type of the nitride semiconductor layer may be formed by using a MOCVD method. The first temperature may be at least 900° C., and the second temperature may be at most 810° C. The first temperature may be higher than the second temperature by at least 100° C., preferably by at least 150° C.

According to the present invention, an ESD tolerance voltage of an LED can be improved.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

Other objects, features and advantages of the present invention will become more apparent from the following detailed description when read in conjunction with the accompanying drawings, in which:

FIGS. 1A to 1D are cross-sectional views showing a method of manufacturing an LED according to an embodiment of the present invention;

FIG. 2A is a graph showing formation temperatures of Comparative Examples II and III; and

FIG. 2B is a graph showing a formation temperature of Example I.

### DESCRIPTION OF THE PREFERRED EMBODIMENTS

A description will now be given of embodiments of the present invention with reference to the accompanying drawings.

The inventors have found that an ESD tolerance voltage of an LED can be improved by forming an active layer, then thermally treating the active layer at a temperature higher than the formation temperature of the active layer, and forming a p-type semiconductor layer at a temperature lower than the thermal treatment temperature. An embodiment of the present invention will be described below.

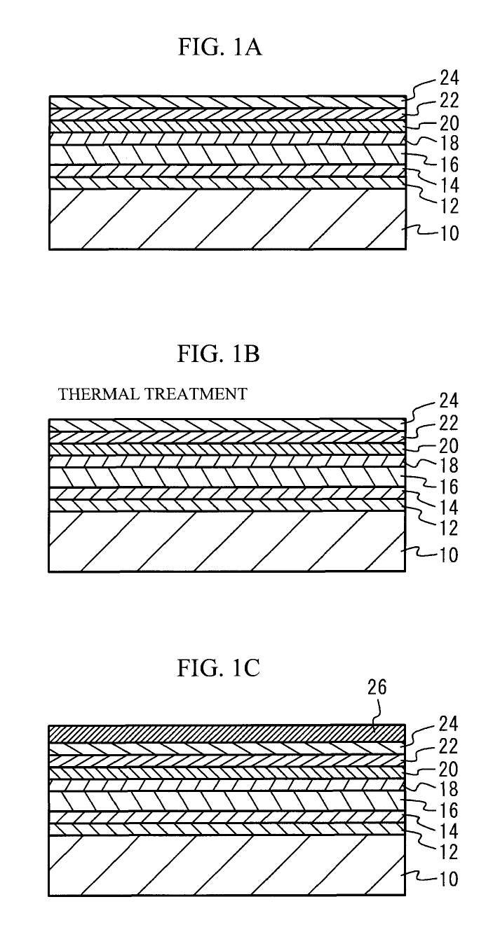

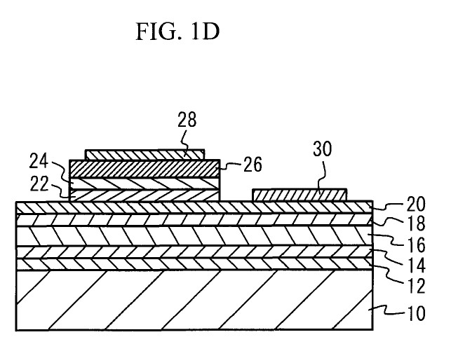

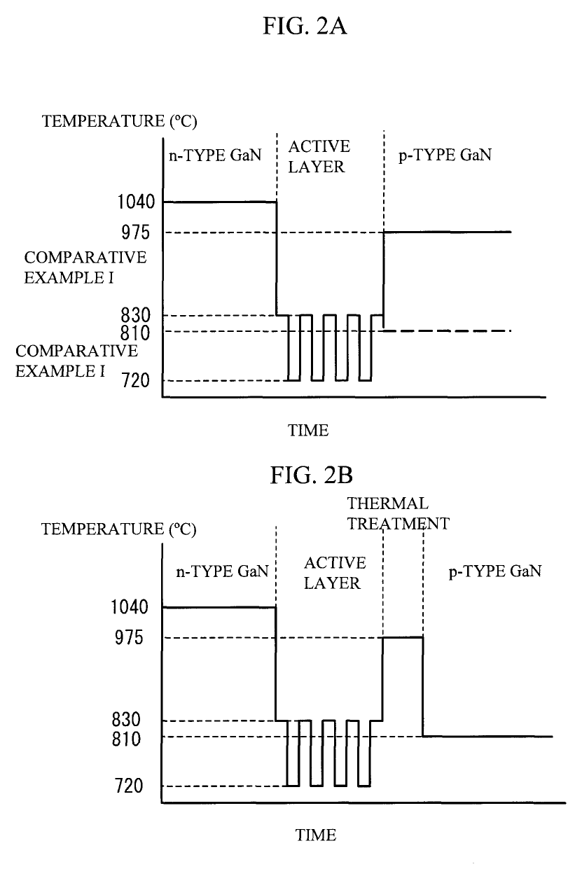

A method of manufacturing a light emitting diode according to the present invention will be described below with reference to FIGS. 1A to 2B.

Referring to FIG. 1A, an AlN buffer layer 12, an Si-doped GaN buffer layer 14, an undoped GaN buffer layer 16, an n-type GaN intermediate layer 18, and an n-type GaN contact layer 20 are formed in sequence on a sapphire substrate 10 having a principal plane of (0001) by using metal organic chemical vapor deposition (MOCVD). An n-type GaN semiconductor layer 22 is formed as a first conductive type of nitride semiconductor according to the present invention on the n-type GaN contact layer 20 by using MOCVD. Then a multi quantum well (MQW) active layer 24 of InGaN/GaN is formed on the n-type GaN semiconductor layer 22 by using MOCVD.

Examples of the formation conditions for the respective layers are as follows.

### (The Formation Conditions for the Aln Buffer Layer 12)

Film thickness: 580 nm

Doping density: Undoped

Material gas: Trimethylaluminum (TMA), NH₃

Carrier gas: Hydrogen

Pressure: 50 Torr

Formation temperatures: 1040° C. (formation temperature I), 1140° C. (formation temperature II)

The temperature is changed from the formation temperature I to the formation temperature II during the formation.

### (The Formation Conditions for the Si-Doped Gan Buffer Layer 14)

Film thickness: 60 nm

Si doping density: 1.5×10¹⁹ cm⁻³

Material gas: Trimethylgallium (TMG), NH₃, SiH₄

Carrier gas: Hydrogen

Pressure: 200 Torr

Formation temperature: 1040° C.

### (The Formation Conditions for the Undoped GaN Buffer Layer 16)

Film thickness: 1330 nm

Doping density: Undoped

Material gas: TMG, NH₃

Carrier gas: Hydrogen

Pressure: 200 Torr

Formation temperature: 1040° C.

(The Formation Conditions for the N-Type GaN Intermediate layer 18)

Film thickness: 1380 nm

Si doping density: 1.5×10¹⁹ cm⁻³

Material gas: TMG, NH₃, SiH₄

Carrier gas: Hydrogen

Pressure: 200 Torr

Formation temperature: 1040° C.

### (The Formation Conditions for the N-Type GaN Contact Layer 20)

Film thickness: 500 nm

Si doping density: 1.5×10¹⁹ cm⁻³

Material gas: TMG, trimethylindium (TMI), NH₃, SiH₄

Carrier gas: Nitrogen

Pressure: 200 Torr

Formation temperature: 830° C.

### (The Formation Conditions for the N-Type GaN Semiconductor Layer 22)

Film thickness: 170 nm

Si doping density: 1.5×10¹⁹ cm⁻³

Material gas: TMG, NH₃, SiH₄

Carrier gas: Hydrogen

Pressure: 100 Torr
Formation temperature: 1040° C.

### (The Formation Conditions for the MQW Active Layer 24)

Film thickness: 65 nm

Layers: Five well layers, six barrier layers

i) The Well Layers: In_{0.16}Ga_{0.84}N
Film thickness: 2.2 nm
Doping density: undoped
Material gas: Triethylgallium (TEG), TMI, NH₃
Carrier gas: Nitrogen
Pressure: 300 Torr
Formation temperature: 720° C.

ii) The Barrier Layers: GaN
Film thickness: 9 nm
Doping density: 5×10¹⁷ cm⁻³
Material gas: TEG, NH₃
Carrier gas: Nitrogen
Pressure: 300 Torr
Formation temperature: 830° C.

Referring to FIG. 1B, thermal treatment is performed on the active layer 24, for example, under the following conditions. The temperature is raised to 975° C. in 90 seconds, held at 975° C. for 300 seconds, and lowered to 810° C. in 180 seconds.

Referring to FIG. 1C, a p-type GaN semiconductor layer 26 is formed as a second type of nitride semiconductor according to the present invention on the active layer 24 at a temperature lower than the above thermal treatment temperature by using an MOCVD method. The formation conditions are as follows.

### (The Formation Conditions for the P-Type GaN Semiconductor Layer 26)

Film thickness: 200 nm

Mg doping density: 4×10¹⁹ cm⁻³

Material gas: TMG, NH₃, Cp₂Mg

(bis(cyclopentadienyl)magnesium)

Carrier gas: Hydrogen

Pressure: 200 Torr

Formation temperature: 810° C.

The n-type GaN semiconductor layer 22, the p-type GaN semiconductor layer 26, and the active layer 24 may be modified in various manners as long as they comprise a nitride semiconductor. Typically, those layers may be formed of AlₓIn_{y}Ga_{1-x-y}N (0≦x<1, 0≦y<1, 0≦x+y<1). For example, the n-type GaN semiconductor layer 22 and the p-type GaN semiconductor layer 26 may be formed of AlGaN or AlInGaN instead of GaN.

The MQW active layer 24 having a combination of well layers and barrier layers may comprise a nitride semiconductor having a combination of InGaN/GaN, InGaN/InGaN, or AlInGaN/AlInGaN. The relationship between band gaps of the respective layers is defined as (the n-type GaN semiconductor layer 22 and the p-type GaN semiconductor layer 26)≧the barrier layers>the well layers.

Referring to FIG. 1D, a dry etching process is performed selectively on a region in which an n-type electrode 30 is to be formed until the n-type InGaN contact layer 20 is exposed. A mesa portions is formed at a region that has not been etched. The mesa portion serves as a light-emitting portion. A p-type electrode 28 of NiAu is formed on a portion of the p-type GaN semiconductor layer 26 by using a vapor deposition method. The p-type electrode 28 is electrically connected to the p-type GaN semiconductor layer 26. An annealing process is performed in the atmosphere at 500° C. so as to form an alloy with the p-type GaN semiconductor layer 26. An n-type electrode 30 of Ta/Al/Pt is formed on a portion of a bottom of the groove by using a vapor deposition method. The n-type electrode 30 has layers of Ta, Al, and Pt in order from the bottom. The n-type electrode 30 is electrically connected to the n-type InGaN contact layer 20. An annealing process is performed in the atmosphere at 500° C. so as to form an alloy with the n-type InGaN contact layer 20. Thus, the structure illustrated in FIG. 1D is formed.

Next, an electrode pad connecting to the p-type electrode 28 and the n-type electrode 30 is formed. Then a protective film of a silicon oxide is formed on a region other than the electrode pad. The electrode pad and the protective film are not shown in the drawings. The substrate 10 is ground so as to have a thickness of 100 μm. The wafer is divided into chips, each of which has an approximate dimension of 350 μm×350 μm, for example, on a rear face of the substrate 10 by using a scribing method. Then those chips are mounted on a package. Thus, an LED is completed. The p-type electrode 28 and the n-type electrode 30 may be formed of ITO (indium tin oxide) or the like.

An LED of Example I was manufactured by the processes described above. An LED of Comparative Example II was manufactured under conditions in which the thermal treatment described in connection with FIG. 1B was not performed and a p-type GaN semiconductor layer 26 as shown in FIG. 1C was formed at 975° C. An LED of Comparative Example III was manufactured under conditions in which a p-type GaN semiconductor layer 26 was formed at 810° C.

FIGS. 2A and 2B are respectively graphs showing temperature profiles during the formation of the n-type GaN semiconductor layer 22 and the active layer 24, the thermal treatment, and the formation of the p-type GaN semiconductor layer 26 with regard to Comparative Examples II and III and Example I. FIG. 2A shows the formation temperatures of Comparative Examples II and III. FIG. 2B shows the formation temperature of Example I. FIGS. 2A and 2B schematically illustrate the numbers of the barrier layers and the well layers in the active layer 24.

As shown in FIG. 2A, in Comparative Example II, the formation temperature was increased to 975° C. after the completion of the formation of the active layer 24. The p-type GaN semiconductor layer 26 was formed at 975° C. Similarly, in Comparative Example III, the p-type GaN semiconductor layer 26 was formed at a formation temperature of 810° C. as shown by a dashed line in FIG. 2B. Meanwhile, in Example I shown in FIG. 2B, the temperature was increased to 975° C. in a MOCVD reactor after the completion of the formation of the active layer 24. The temperature was held for a certain period of time and then lowered to 810° C. Thereafter, the p-type GaN semiconductor layer 26 was formed at 810° C.

The LEDs of Example I and Comparative Examples II and III were evaluated in reverse ESD tolerance voltage. The application of ESD was performed with use of a human body model to which a resistance of 1.5 kΩ and a capacity of 100 pF were added. Breakdowns were examined before and after the (five-time) application of a reverse voltage. When no breakdowns were detected, the reverse voltage was increased. The ESD tolerance voltage was defined as a voltage at which an LED was broken. The determination of the breakdown was conducted based on light emission and changes of the voltage value when a current flowed in a reverse direction.

Table 1 shows comparison between the ESD tolerance voltages of Example I and Comparative Examples II and III. The ESD tolerance voltages of Comparative Examples II and III were 500 V and 571 V, respectively. The ESD tolerance voltage of Example I was 3857 V.

TABLE 1

| | | P-type GaN | |
|---|---|---|---|
| | Thermal | semiconductor | ESD tolerance |
| | treatment | layer | voltage |
| Example I | 975° C. | 810° C. | 3857 V |
| Comparative | N/A | 975° C. | 500 V |
| Example II | | | |
| Comparative | N/A | 810° C. | 571 V |
| Example III | | | |

With regard to the broken LED elements in Comparative Examples II and III, observation was made on appearance of mesa portions including the n-type GaN semiconductor layer 22, the active layer 24, and the p-type GaN semiconductor layer 26 shown in FIG. 1D, and patterns of light-emitting regions. Neither deterioration defects nor regions that emitted no light, which would have been caused by ESD breakdown, were observed on side surfaces of the mesa portions but only on flat portions of the mesa portions. Such deterioration defects and regions were produced randomly on the flat portions. When the deterioration defects were observed by using a SEM, deterioration was present on the p-type electrode 28 and the underlying semiconductor crystalline layer. The same result was obtained when the p-type electrode 28 was formed of ITO. In view of these results, it is conceivable that the side surfaces of the mesa portions or the p-type electrode 28 does not cause ESD breakdowns, but the internal semiconductor crystalline structure of the mesa portions causes ESD breakdowns. If the semiconductor crystalline structure of the mesa portions causes breakdown, the largest ESD electric field is applied to the vicinity of PN junctions, which corresponds to the active layer 24 shown in FIG. 1D, at the time of the application of the ESD.

In Comparative Example II, the p-type GaN semiconductor layer 26 was formed at a high formation temperature. Accordingly, a relatively large amount of a dopant (Mg) for the p-type GaN semiconductor layer 26 diffused into the active layer 24. It is conceivable that this diffusion of the dopant caused a lowered ESD tolerance voltage. In Comparative Example III, since the formation temperature of the p-type GaN semiconductor layer 26 was low, diffusion of a dopant into the active layer 24 was suppressed. Nevertheless, the ESD tolerance voltage remained low.

By contrast, in Example I, after the formation of the active layer 24, thermal treatment was performed on the active layer 24. Thus, a high ESD tolerance voltage could be obtained. Example I differed from Comparative Example III in that thermal treatment was performed before the formation of the p-type GaN semiconductor layer 26. It appears that the thermal treatment improved the crystallinity of the semiconductor which formed the active layer 24. It is thus conceivable that the ESD tolerance voltage was improved as a result of the improved crystallinity. Furthermore, it can be seen from the result of Comparative Example II that the formation temperature of the p-type GaN semiconductor layer 26 should be lower than the thermal treatment temperature in order to prevent diffusion of a dopant from the p-type GaN semiconductor layer 26.

It is desirable that the thermal treatment temperature be at least 900° C. because the crystallinity of the active layer 24 can significantly be improved. Furthermore, it is desirable that the p-type GaN semiconductor layer 26 be formed at 810° C. or less in order to prevent a dopant from diffusing into the active layer 24.

In order to increase an ESD tolerance voltage of an LED, it is desirable that the thermal treatment temperature as described in connection with FIG. 1B is higher than the formation temperature of the p-type GaN semiconductor layer 26 as described in connection with FIG. 1C by about 100° C. or more. It is more preferable that the thermal treatment temperature is higher than the formation temperature of the p-type GaN semiconductor layer 26 by about 150° C. or more.

The present embodiment uses a sapphire substrate 10. Nevertheless, an Si substrate, an SiC substrate, or a GaN substrate may be used. Furthermore, the n-type GaN semiconductor layer 22 and the p-type GaN semiconductor layer 26 may employ a nitride semiconductor layer other than a GaN semiconductor layer as long as it serves as a semiconductor layer having an index of refraction greater than that of the active layer 24. Moreover, the active layer 24 may employ a nitride semiconductor layer other than a GaN or InGaN semiconductor layer as long as it serves as a layer that emits light. Furthermore, the first conductive type may be p-type, and the second conductive type may be n-type.

Although a certain preferred embodiment of the present invention have been shown and described in detail, it should be understood that the present invention is not limited to the specific embodiment. It would be apparent to those skilled in the art that many modifications and variations may be made therein without departing from the spirit and scope of the present invention.

The present application is based on Japanese Patent Application No. 2007-266166 filed Oct. 12, 2007, the entire disclosure of which is hereby incorporated by reference.

What is claimed is:

1. A method of manufacturing a light emitting diode, the method comprising:
forming an active layer of a nitride semiconductor on a first conductive type of a nitride semiconductor layer;
thermally treating the active layer at a first temperature; and
forming a second conductive type of a nitride semiconductor layer on the active layer at a second temperature lower than the first temperature.

2. The method as claimed in claim 1, wherein the second conductive type of the nitride semiconductor layer comprises one of GaN, AlGaN, and AlInGaN.

3. The method as claimed in claim 1, wherein the active layer includes a multi quantum well.

4. The method as claimed in claim 3, wherein the active layer comprises any one of combinations of InGaN/GaN, InGaN/InGaN, and AlInGaN/AlInGaN

5. The method as claimed in claim 1, wherein the active layer is formed by a MOCVD method.

6. The method as claimed in claim 1, wherein the second conductive type of the nitride semiconductor layer is formed by a MOCVD method.

7. The method as claimed in claim 1, wherein the first temperature is 900° C. or higher.

8. The method as claimed in claim 1, wherein the second temperature is 810° C. or lower.

9. The method as claimed in claim 1, wherein the first temperature is higher than the second temperature by 100° C. or more.

10. The method as claimed in claim 1, wherein the first temperature is higher than the second temperature by 150° C. or more.
